(19) United States
(12) Patent Application Publication
(10) Pub. No.: US 2011/0198033 A1
(43) Pub. Date: Aug. 18, 2011

(54) SHUTTER DEVICE AND VACUUM PROCESSING APPARATUS

(75) Inventor: Masashi Tsujiyama, Tokyo (JP)

(73) Assignee: CANON ANELVA CORPORATION, Kawasaki-shi (JP)

(21) Appl. No.: 13/027,974

(22) Filed: Feb. 15, 2011

(30) Foreign Application Priority Data
Feb. 16, 2010 (JP) 2010-31589
Dec. 22, 2010 (JP) 2010-285356

(51) Int. Cl. C23F 1/02; C23C 14/34; B05C 11/00

(52) U.S. Cl. 156/345.3; 204/298.11; 118/504

(57) ABSTRACT

A shutter device having two shutter plates, which shield between an IBS and a substrate, is configured such that the two shutter plates are disposed at symmetrical positions across the IBS and can perform an opening/closing operation in synchronization with a rotation of a rotation-link-member which is rotatably disposed surrounding the IBS. With the configuration, the shutter device can reduce an offset of a shield range in the opening/closing operation.

### BACKGROUND OF THE INVENTION

1. Field of the Invention

The invention relates to a shutter device and a vacuum processing apparatus, and more particularly to a shutter device including shutter plates which shield between an ion source or an evaporation source and a substrate when respective processes are performed in a vacuum processing apparatus such as a sputtering device, an etching apparatus, and the like and to a vacuum processing apparatus including the shutter device.

2. Description of the Related Art

A physical vapor deposition device and an etching device are ordinarily used as a vacuum processing apparatus. The physical vapor deposition device includes an evaporation source such as a crucible, a cathode, and the like, and further the etching device includes an etching source such as an ion source and the like. It is preferable to make a film forming material and an ion beam generated from the evaporation source and the etching source uniform and stable. For the purpose, an operation for previously generating a sputtering film and an etching beam before a substrate is processed is necessary as a preparation operation of the evaporation source and the etching source.

Since a sputtering film is deposited on and an etching beam is emitted onto the substrate also in the preparation operation, it is necessary to shield the substrate to be processed so that the substrate is not influenced by the film forming material and the etching beam. Further, when processing of the substrate is finished, since it is necessary to finish the processing at a predetermined timing, the substrate must be promptly shielded from the film forming material and the etching beam. To shield a substrate from a film forming material and an etching beam flying to the substrate, the vacuum processing apparatus includes an opening/closing shutter mechanism (refer to, for example, Patent Documents 1 to 8).

An example of a conventional shutter mechanism will be described. First, FIG. 6A to 6C and FIG. 7A to 7C show shutter mechanisms disclosed in Patent Documents 1 and 2, respectively. The shutter mechanism (pendulum operation type) shown in FIG. 6A to 6C includes a shutter plate 111, which moves in a right/left direction around a rotating shaft and performs an opening/closing operation. Further, a shutter mechanism (linear operation type) shown in FIG. 7A to 7C includes a shutter plate 112, which moves in a forward/backward direction and performs an opening/closing operation.

Prior art documents

Patent Documents

Patent Document 1: Japanese Patent Application Laid-Open No. 2004-300560

Patent Document 2: Japanese Patent Application Laid-Open No. 2002-353172

Patent Document 3: Japanese Patent Application Laid-Open No. 2007-016298

Patent Document 4: Japanese Patent Application Laid-Open No. 2001-110344

Patent Document 5: Japanese Patent Application Laid-Open No. 2002-075968

Patent Document 6: Japanese Patent Application Laid-Open No. 2000-294187

Patent Document 7: Japanese Patent Application Laid-Open No. 2009-155706

Patent Document 8: Japanese Patent Application Laid-Open No. 2002-167661

In the shutter mechanisms of “the pendulum operation type” shown in FIG. 6A to 6C and “the linear operation type” shown in FIG. 7A to 7C, the shutter plates move horizontally. As shown in FIG. 6C and FIG. 7C, in the opening/closing operation, since shutter plates move from one end side of a to-be-shielded-material G to the other end side thereof, a portion a, which is partly shielded, and a portion b, which is not partly shielded, occur during the operation. That is, a problem arises in that a shield range is offset while the shutter plates operate.

In view of the above problem, an object of the invention is to provide a shutter device, which can reduce an offset of a shield range in an opening/closing operation, and a vacuum processing apparatus.

### SUMMARY OF THE INVENTION

A shutter device according to the invention is a shutter device which includes shutter plates that shield between a process-generation-source and a substrate disposed in a vacuum vessel and is characterized by including the shutter plates which are rotated about rotating shafts supported by the vacuum vessel, a rotation-link-member rotatably disposed around the process-generation-source, and a drive source which drives the rotation-link-member in rotation, wherein the rotation-link-member is disposed surrounding a process-source-emitting-portion of the process-generation-source, and as the rotation-link-member rotates, the shutter plates rotate about the rotating shafts.

The offset of the shield range can be reduced in the opening/closing operation by using the shutter device according to the invention. Further, since operation ranges of the respective shutter plates are reduced by dividing the shutter, an operation-speed can be increased.

### BRIEF DESCRIPTION OF THE DRAWINGS

FIG. 1 is a schematic sectional view of an IBE apparatus according to a first embodiment of the invention when the IBE apparatus is viewed from a side surface.

FIGS. 2A and 2B are front views of a shutter device when the shutter device is viewed from an A direction of FIG. 1, in which FIG. 2A shows a time at which shutters are opened and FIG. 2B shows a time at which the shutters are closed.

FIG. 3 is a sectional view taken along a line II-II of FIG. 2.

FIGS. 4A and 4B are operation schematic views of the shutter device according to the first embodiment of the invention, in which FIG. 4A is a sectional view taken from an A direction of FIG. 1, and FIG. 4B is an A fragmentary view along a line I-I in FIG. 1.

FIGS. 5A and 5B are front views of a shutter device according to a second embodiment of the invention, in which FIG. 5A shows a time at which shutters are opened and FIG. 5B shows a time at which the shutters are closed,

FIG. 6A to 6C are a schematic view of a conventional shutter device, and

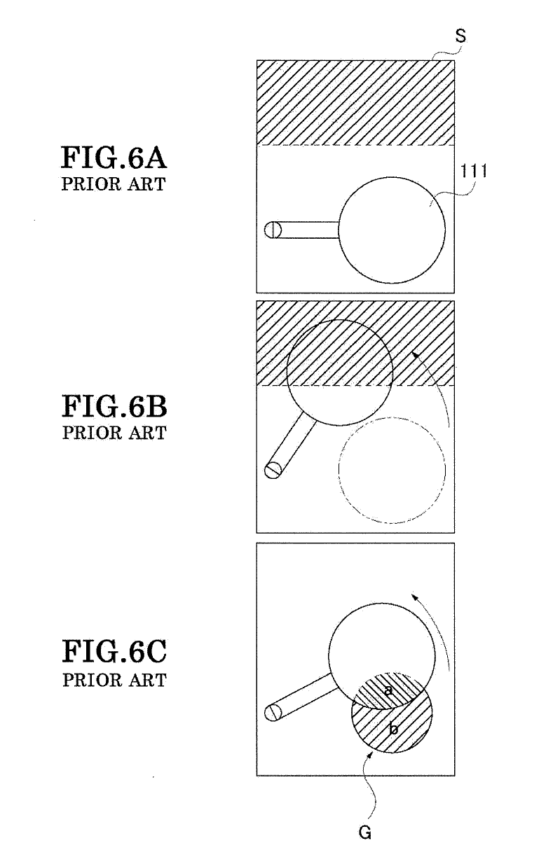

FIG. 7A to 7C are a schematic view of a conventional shutter device.

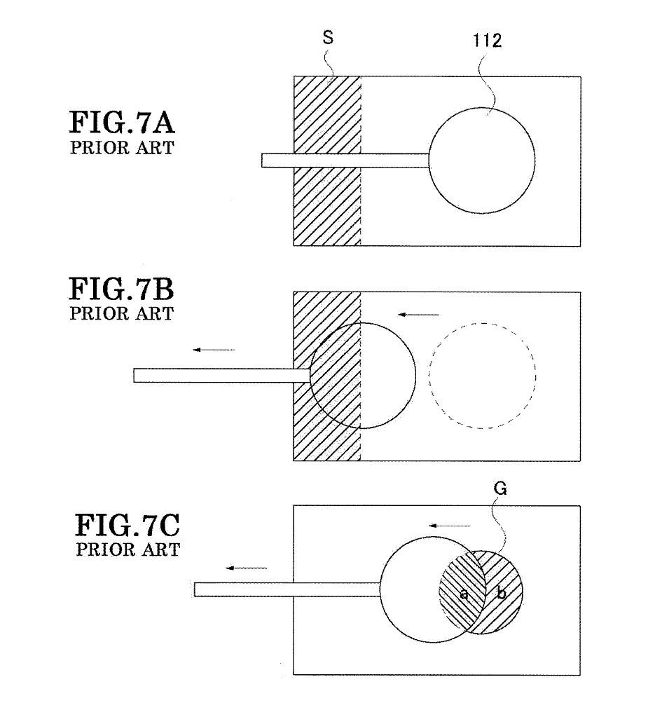

### DESCRIPTION OF THE PREFERRED EMBODIMENTS

First embodiment

A first embodiment of the invention will be described below with reference to the drawings. It goes without saying that members, dispositions, and the like described below are an example in which the invention is embodied, do not restrict the invention, and can be variously changed and modified. Note that a term “process-generation-source” in the specification is used to show any of an ion source such as an IBS and the like and an evaporation source such as a sputtering cathode, a crucible, and the like.

Note that, in the embodiment, although a description is made by exemplifying an ion beam etching apparatus (IBE apparatus) as a vacuum processing apparatus, the invention is not limited to the ion beam etching apparatus. The shutter device according to the invention can be preferably applied also to a vacuum processing apparatus, for example, other etching apparatus and sputtering apparatus, a PVD apparatus, a CVD apparatus, and the like. Even when the shutter device according to the embodiment is installed in a vacuum processing apparatus, all the operation mechanisms can be used in any of a vacuum environment and an atmospheric environment. Further, it is needless to say that the shutter device according to the embodiment can be applied as a shutter device which shields a substrate from a vapor deposition source in addition to the shutter device of the IBE apparatus.

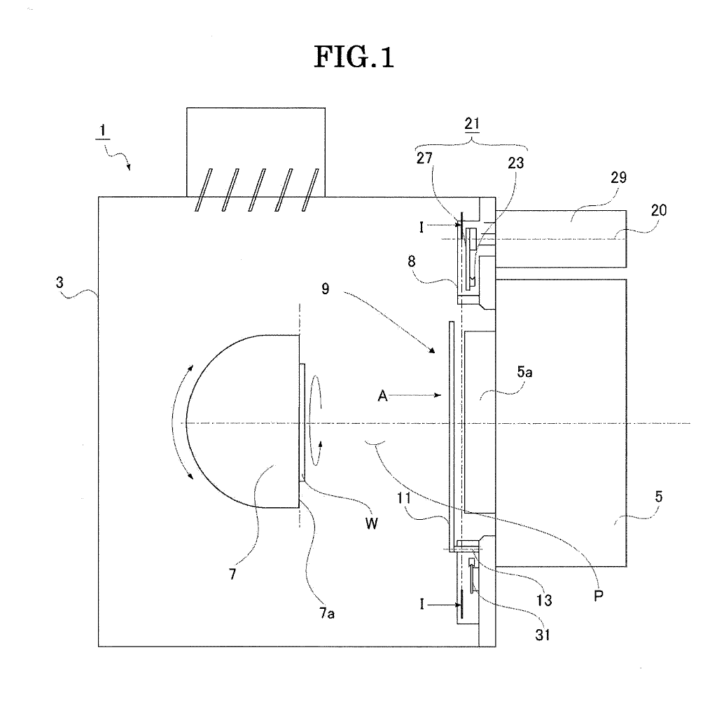

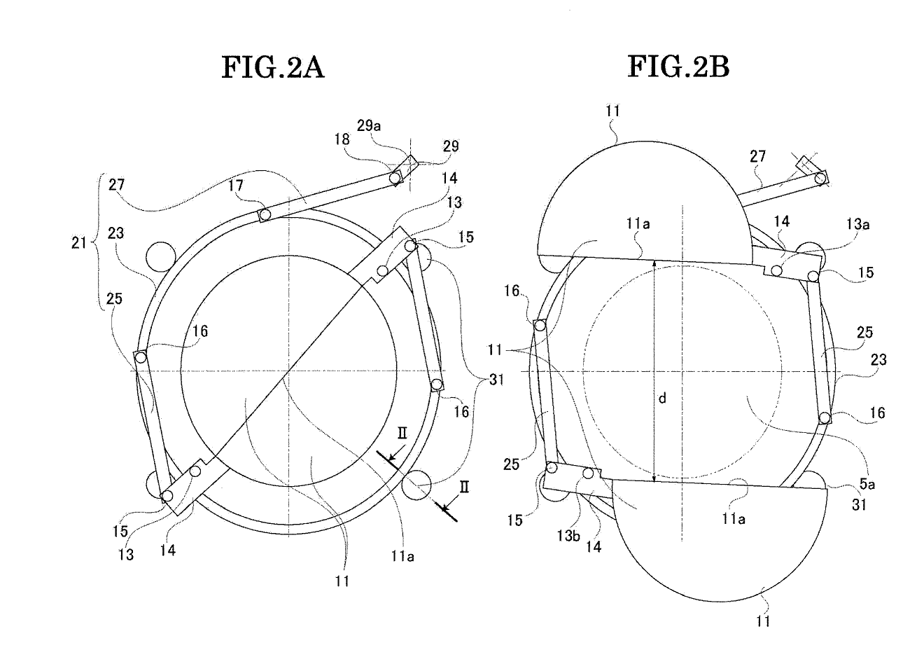

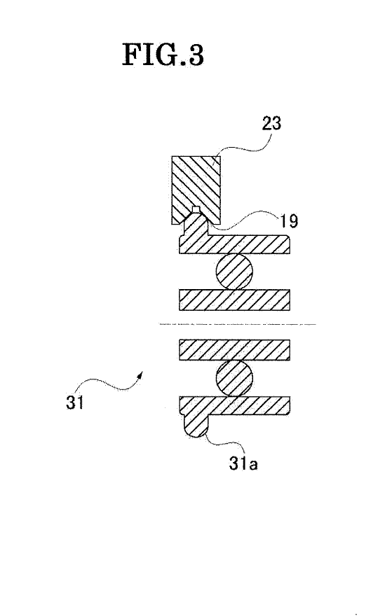

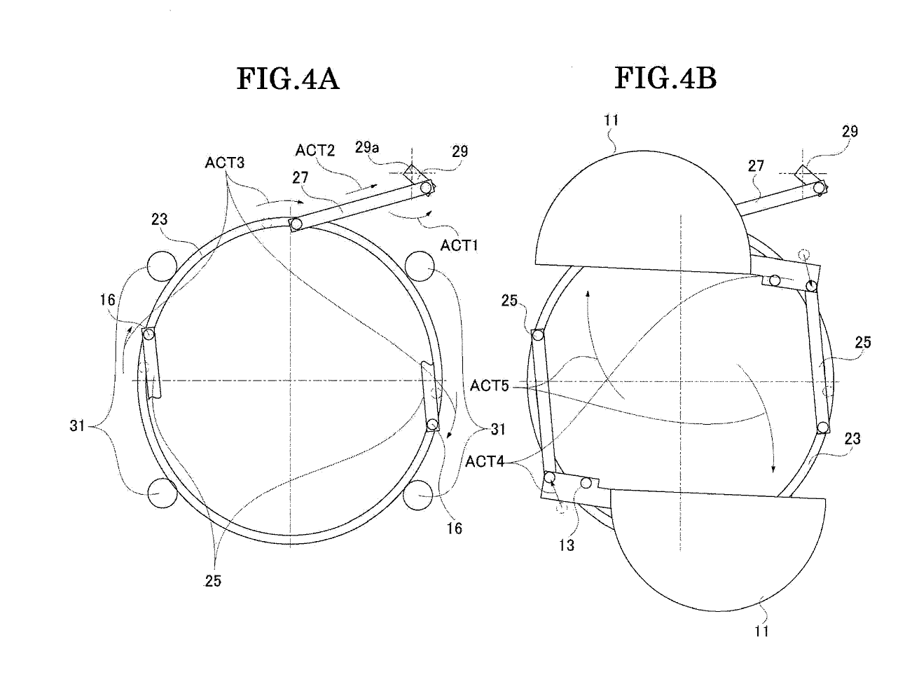

FIGS. 1 to 4 are drawings as to a shutter device or an ion beam etching apparatus (IBE apparatus) according to the first embodiment of the invention, wherein FIG. 1 is a schematic sectional view of the IBE apparatus when the IBE apparatus is viewed from a side surface, FIG. 2 is a fragmentary view (front view) of the shutter device when the shutter device is viewed in an A direction of FIG. 1 (a part (a) shows a time at which shutters are opened and a part (b) shows a time at which the shutters are closed), FIG. 3 is a II-II sectional view of FIG. 2, and FIG. 4 is an operation explanatory view of the shutter device (a part (a) is a I-I sectional view and a part (b) is an A fragmentary view). Note that the drawings are shown by partly omitting components to prevent that the drawings become complex.

An ion beam etching device 1 (IBE apparatus 1) shown in FIG. 1 includes at least an etching source 5 (ion beam source, IBS), a substrate stage 7, and a shutter device 9 in a vacuum vessel 3, the IBS 5 is disposed to a side surface of the vacuum vessel 3, and the substrate stage 7 is disposed in confrontation with the IBS 5.

The IBE apparatus 1 is a device which emits ions onto a substrate W placed on the substrate stage 7 from the IBS 5 and etches a predetermined laminated film of the substrate W. The substrate stage 7 includes a substrate holding portion 7a which holds the substrate W and a turning support portion (not shown) which supports the substrate holding portion 7a to the vacuum vessel 3 as main components.

The substrate holding portion 7a can hold the substrate W by a mechanical-chuck-mechanism an electrostatic-chuck-mechanism, and can rotate the substrate W together with the substrate holding portion 7a. Further, the turning support portion can turn with respect to the vacuum vessel 3 and can change a direction of the substrate holding portion 7a. That is, the turning support portion can change an angle of a film forming surface of the substrate W to an incident direction of the ions from the IBS 5. The change of the incident angle of the ions to the film forming surface of the substrate W permits the ions to be incident on the film forming surface of the substrate W from an oblique direction, thereby etching can be performed with a higher accuracy.

The IBS 5 is a device which ionizes gas by plasma and emits resultant ions onto the substrate W. In the embodiment, although Ar gas is ionized, ions to be emitted are not limited to Ar ions. For example, Kr gas Xe gas, O₂ gas, and the like may be used. Further, a neutralizer (not shown) is disposed on a side wall surface of the IBS 5 to neutralize the charges of the ions emitted from the IBS 5.

The shutter device 9 is interposed between the IBS 5 and the substrate W on the substrate stage 7 and includes shutter plates 11 and a link mechanism 21, which opens and closes the shutter plates 11 as main components. The ions emitted from the IBS 5 onto the substrate W can be shielded before the ions reach the substrate W by an opening/closing operation of the shutter device 9. Note that the IBE apparatus 1 includes a partition 8 which partitions a space in which the link mechanism 21 is disposed and a process space P in which etching and the like are performed. Particles, which are generated in the space in which the link mechanism is disposed and flow out to the process space P, can be reduced by the partition 8.

A configuration of the shutter device 9 will be described with reference to front views of the shutter device shown in FIGS. 2A and 2B. The shutter device 9 is configured by including the shutter plates 11 the link mechanism 21 composed of a rotation link member 23 (rotation-link-member), and the like.

The shutter plates 11 are a so-called two-part shutter and use two approximately semicircular plate-like members as a set. The two shutter plates 11 are turned, respectively, using shutter rotating shafts 13 (13a, 13b) as centers of rotation. The two shutter plates 11 can be rotated in a reverse direction, respectively, and a substrate side of the IBS 5 can be shielded by rotating the two shutter plates 11 to a position where linear portions lla of the shutter plates 11 come in contact with each other (refer to FIG. 2A). Note that a state, in which the IBS 5 is shielded by the shutter plates 11, is called “a closed state” (state of FIG. 2A).

Further, the ions emitted from the IBS 5 can be caused to be incident on the substrate side by disposing the two shutter plates 11 at positions having a distance therebetween. In particular, in a state, in which a distance d between the linear portions 11a is more separated from a diameter of an ion emitting portion 5a of the IBS 5, the substrate side of the IBS 5 can be largely opened (refer to FIG. 2B). A state, in which the shutter plates 11 is opened, is called “an open state” (state of FIG. 2B).

The shutter rotating shafts 13 (13a, 13b) are approximately rod-like columns which support the shutter plates 11 and rotatably attached to a wall side of the vacuum vessel 3. The approximately semicircular shutter plates 11 are formed with extending portions 14 extending from parts of the shutter plates 11, and the shutter rotating shafts 13 (13a, 13b) and coupling portions 15 to be described later are attached to the extending portions 14, respectively.

The coupling portions 15 are locking portions formed externally of the shutter rotating shafts 13 at positions away at a predetermined distance from the shutter rotating shafts 13, and one end sides of coupling link members 25 (coupling-link-members) to be described later are rotatably locked to the coupling portions 15. That is, when the coupling portions 15 are applied with a drive force in a forward/rearward direction via the coupling link members 25, the shutter plates 11 can be caused to perform a rotating motion using the shutter rotating shafts 13 as centers of rotation.

The link mechanism 21 is a mechanism which transmits the drive force to the coupling portions 15 of the shutter plates 11 and causes the shutter plates 11 to perform the opening/closing operation. A configuration of the shutter device 9 will be described with reference to FIG. 2. The link mechanism 21 is configured by including the coupling link members 25 whose one end portions are coupled with the coupling portions 15, a rotation link member 23 coupled with the other ends of the coupling link members 25, a drive link member 27 (drive-link-member) which transmits a rotational force to the rotation link member 23, a drive source 29 which drives the drive link member 27, and the four bearings 31 which rotatably support the rotation link member 23.

The coupling link members 25 are approximately rod-like quadrangular prisms, and the coupling portions 15 and coupling portions 16 are coupled with both the end sides of the coupling link members 25, respectively. The coupling link members 25 have such a structure that one end sides of the coupling link members 25 are rotatably locked to the coupling portions 15 of the extending portions 14. Likewise, the coupling link members 25 have such a structure that the other end sides of the coupling link members 25 are rotatably locked to the rotation link member 23 via the coupling portions 16. Note that the coupling portions 15, 16, a coupling portion 17, and a coupling portion 18 in the embodiment may be configured to have bearings so that angles, at which to-be-coupled-members are coupled, can be smoothly changed.

The rotation link member 23 is a ring-shaped member which is rotatably installed surrounding an outer periphery of the IBS 5, and an outer periphery of the rotation link member 23 is rotatably supported by the four bearings 31 disposed around the outer periphery of the rotation link member 23. Specifically, the rotation link member 23 is disposed surrounding the ion emitting portion 5a (process-source-emitting-portion) of the IBS 5, and a rotation center when the rotation link member 23 rotates is set to a center of the ion emitting portion 5a. Note that, in the embodiment, although the rotation link member 23 is formed in a ring shape, it is needless to say that the rotation link member 23 may be formed in a C-shape. Further, it is sufficient that the rotation center of the rotation link member 23 is set inside of a range in which the rotation link member 23 may be attached, and it is needless to say that the rotation center can be set to a position other than the center of the ion emitting portion 5a. The rotation link member 23 is formed with openings (locking portions) at three positions. Among the three openings, two openings (coupling portions 16) are formed at 180-degree symmetrical positions, and a different coupling link member 25 is locked to each of the two openings.

That is, the coupling link members 25 can transmit power to the shutter plates 11 sides by the rotation of the rotation link member 23 and can rotate the shutter plates 11. Further, the remaining one opening (coupling portion 17) formed to the rotation link member 23 is locked with one end portion side of the drive link member 27 to be described later.

The drive link member 27 is an approximately rod-like quadrangular prism which couples the rotation link member 23 with the drive source 29. The drive link member 27 has such a structure that one end portion of the drive link member 27 is locked to the rotation link member 23 via the coupling portion 17. In contrast, the drive link member 27 has such a structure that the other end portion of the drive link member 27 is locked to the drive source 29 via the coupling portion 18. Accordingly, the rotation link member 23 can be driven in rotation via the drive link member 27 by driving the drive source 29.

The drive source 29 is an operation drive source of the shutter device 9 which performs a repeatedly rotating operation at a finite angle about a drive rotating shaft 29a, and, as described above, the drive source 29 is coupled with the other end portion (coupling portion 18) of the drive link member 27.

Accordingly, when the power source 29 performs a rotation operation, the drive link member 27 transmits the power to the rotation link member 23 and rotates the rotation link member 23. The rotation of the rotation link member 23 causes the shutter plates 11 to rotate via the coupling link members 25. Note that the finite angle of the drive source 29 determines the positions of “the closed state” and “the open state” of the shutter plates 11. Note that the shutter plates 11 are attached with tensile springs (not shown) which urge the shutter plates 11 to both the sides in a close direction and in an open direction so that a vibration when the power source 29 is driven and accelerated and decelerated and a vibration from the outside when the power source 29 is not driven can be reduced.

A support structure of the rotation link member 23 will be described based on a II-II sectional view of FIG. 2 shown in FIG. 3. The rotation link member 23 has a V-shaped groove 19 (groove portion) around the outer peripheral portion (outer periphery), and the four bearings 31 have convex curved surface portions 31a (convex portions having an arc-shaped cross section) around outer peripheral portions (outer peripheries), respectively. The rotation link member 23 is supported so that the curved surface portions 31a of the bearings 31 are fit into the V-shaped groove 19 of the rotation link member 23, respectively.

Accordingly, the bearings 31 can smoothly rotate the rotation link member 23 without removing from the V-shaped groove 19. Note that since the V-shaped groove 19 of the rotation link member 23 is in point contact with the curved surface portions 31a of the bearings 31, no rubbing contact is caused by a difference between outer and inner diameters in rotation. Accordingly, dusts generated when the rotation link member 23 rotates can be reduced.

In the embodiment, although the rotation link member 23 is supported using the four bearings 31, it is needless to say that the embodiment can be configured to use three or five or more bearings 31. Contrary to the embodiment, it is needless to say that a combination, in which V-shaped grooves (groove portions) are formed around the outer peripheral portions (outer peripheries) of the bearings 31 and a convex curved surface portion (convex portion) is formed around the outer peripheral portion (outer periphery) of the rotation link member 23, maybe employed. Further, contrary to the embodiment, it is needless to say that a combination, in which an inner peripheral portion of the rotation link member 23 has a V-shaped groove, and the inner periphery is rotatably supported by the bearings 31 installed around the inner peripheral portion, may be employed.

An operation of the shutter device 9 will be described based on operation explanatory views of the shutter device of FIGS. 4A and 4B. FIG. 4A is a sectional view of FIG. 1 taken along the line I-I, and FIG. 4B is a fragmentary view (front view) from the A direction of FIG. 1. When the drive source 29 rotates (ACT1), since the drive link member 27 pulls the rotation link member 23 (ACT2), the rotation link member 23 rotates (ACT3) . When the rotation link member 23 rotates, since the coupling link members 25 pull the shutter plates 11 (ACT4) , the shutter plates 11 rotates about the shutter rotating shafts 13 and perform an open operation (ACT5) . Note that the ACT1—the ACT5 are associated with a motion of the single drive source 29. Accordingly, in the ACT5, although the two divided shutter plates 11 perform the open operation depending on a rotation angle of the drive source 29, respectively, at the time, the two shutter plates 11 perform a synchronized motion. Further, the two shutter rotating shafts 13 are disposed at a symmetrical position with each other across the center of the ion emitting portion 5a, and the two shutter plates 11 operate while keeping geometrically symmetrical dispositions.

Second embodiment

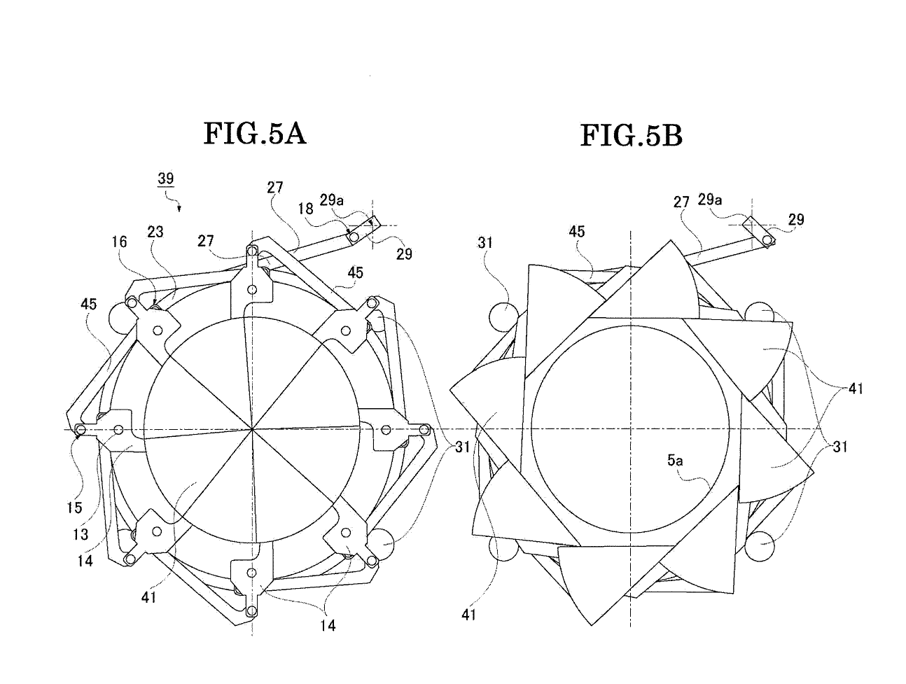

FIGS. 5A and 5B are front views of a shutter device according to a second embodiment of the invention, and FIG. 5A and 5B show a closed state and an open state of the shutter device, respectively. Note that, in the embodiment described below, members, dispositions, and the like which are the same as those of the first embodiment are denoted by the same reference numerals and a detailed explanation thereof will not be repeated here.

In the shutter device 39 according to the embodiment, a shutter is divided to eight shutter plates. The eight shutter plates 41 have shutter rotating shafts 43, respectively, as well as are coupled with coupling link members 45. Note that the respective coupling link members 45 are coupled with a rotation link member 23 likewise the shutter device according to the first embodiment. Further, since a support mechanism of the coupling link members 45 supported by bearings 31, a coupling structure of the coupling link members 45 with a drive link member 27, and the like are the same as the shutter device of the first embodiment, a detailed description thereof will not be repeated here.

The respective eight-divided shutter plates 41 are formed in approximately triangular shape. Further, as the rotation link member 23 rotates, the respective shutter plates 41 can rotate about the shutter rotating shafts 43 via the coupling link members 45. At the time, since the shutter plates 41 rotate in a state that the shutter plates 41 have a minute gap to adjacent shutter plates, the eight shutter plates 41 operate in their entireties so that an octagonal opening region spreads or contracts. That is, the shutter plates 41 have a function as a diaphragm which adjusts a width of an ion beam emitted from an IBS 5.

Note that when a number of the shutter plates 41 is increased, since the opening region is made near to a circular shape, a shape of the ion beam whose size is reduced can be made nearer to a circular shape. Further, the shape of the opening region can be made near to the circular shape also by forming sides of the respective shutter plates 41 in a curved state.

The eight-divided shutter plates 41 are configured such that no gap is formed between the adjacent shutter plates 41, respectively. The embodiment employs a structure in which the adjacent shutter plates 41 are disposed with a step in an up/down direction and edge portions of the adjacent shutter plates 41 are overlapped with each other in the up/down direction. With the disposition, when the shutter device is closed, since the adjacent shutter plates 41 are disposed so that the edge portions of the adjacent shutter plates 41 overlap in the up/down direction (in a flying direction of a process source), the shutter device can reliably shield between a process-generation-source and a substrate. Note that the same effect can be obtained even when the respective shutter plates 41 are disposed in tilt like a screw.

Further, when the structure, in which the edge portions of the adjacent shutter plates 41 are overlapped with each other, is insufficient, a high shield effect can be obtained by employing a labyrinth structure. Specifically, a preferable configuration is such that the edge portions of the shutter plates 41 have a double structure in the up/down direction so that when a shutter is closed, edge portions of the adjacent shutter plates 41 enter gaps of the double structure.

Further, in a configuration having three or more shutter plates, it is difficult to perfectly close a center portion of the shutter in accuracy. Accordingly, it is preferable to form only one of the shutter plates in shape by which the center portion of the shutter is shielded. In particular, the structure can be preferably employed in shutter plates disposed with a step in the up/down direction.

The other effects common to the first embodiment and the second embodiment of the invention will be described below. When the shutter devices 9, 39 according to the invention are used, since it is sufficient that a space, which has a size in which the divided shutter plates 11, 41 can be accommodated, is available, the devices can be reduced in size and a degree of freedom of design can be improved. As the space in which the shutter plates 11, 41 are accommodated, spaces, in which the respective shutter plates 11, 41 can be disposed, can be disposed in dispersion around an ion source and a vapor deposition source (process-generation-source). Further, the shutter rotating shafts of the shutter plates are disposed at the symmetrical positions across the center of the ion emitting portion 5a. Therefore, since the shutter plates 11, 41 and the other components can be geometrically disposed in symmetry, an environment in the vacuum vessel 3 can be made to a more uniform condition.

Further, even if the shutter plates 11, 41 are divided, since one set of the drive source 29 is employed, the operations of the shutter plates 11, 41 can be synchronized via the rotation link member 23. Since the drive source 29 is connected to the rotation link member 23 via the drive link member 27, the drive source 29 can be installed at a location away from the shutter rotating shafts 43. Further, since operation ranges of the respective shutter plates 11, 41 are reduced by dividing the shutter, operation speeds of the shutter devices 9, 39 can be increased.

Since the rotation link member 23 is supported by the structure in which the curved surface portions 31a of the bearings 31 are fit into the V-shaped groove 19 formed around the outer periphery of the rotation link member 23, the bearings 31 can be prevented from removing from the V-shaped groove 19. Further, since the V-shaped groove 19 is in contact (point contact) with the curved surface portions 31a without rubbing the curved surface portions 31a, an effect of reducing generation of dusts can be obtained. Further, since the space, in which the movable member (link mechanism 21) such as the drive source 29, the rotation link member 23, and the like are disposed, is partitioned from the process space P, in which the etching and the like are performed, by the partition 8, the particles, which are generated in the space in which the link mechanism is disposed and flow out into the process space P, can be reduced.

As the shutter devices according to the invention, although the two-part shutter plates 11 and the eight-part shutter plates 41 are explained, it is needless to say that the shutter device can be configured even by four-part shutter plates, five-part shutter plates, and the like. Further, in the shutter devices 9, 39 described above, the respective shutter plates are configured to geometrically operate in symmetry. As described above, this is because it is preferable to geometrically operate the respective shutter plates in symmetry to set a condition such as a potential in the vacuum vessel 3 uniform. However, the shutter devices according to the invention are not limited to the configuration in which the respective shutter plates are geometrically operated and disposed in symmetry. When a space in the vacuum vessel 3 is offset, directions in which the shutter plates are operated may be also offset and the shutter plates may be also disposed in an offset state.

Using the shutter devices according to the invention can reduce an offset of a shield range in the opening/closing operation. Further, operation ranges of the respective shutter plates are reduced by dividing the shutter, an operation speed can be increased. Otherwise, when the shutter devices according to the invention are used, it is sufficient that the space, which has the size in which the divided shutter plates can be accommodated, is available, the devices can be reduced in size and the degree of freedom of design can be improved. As the space in which the shutter plates are accommodated, the spaces, in which the respective shutter plates can be stored, can be provided in dispersion around the ion source and the vapor deposition source (process-generation-source). Therefore, since the shutter plates and the other components can be geometrically disposed in symmetry, a condition in the vacuum vessel can be made more uniform.

Further, even if the shutter plates are divided, since the one set of the drive source is employed, the operations of the shutter plates can be synchronized via the rotation link member. Since the drive source is connected to the rotation link member (rotation-link-member) via the drive link member, the drive source can be installed at the location away from the shutter rotating shafts.

Since the rotation link member is supported by the structure in which the curved surface portions of the bearings are fit into the V-shaped groove formed around the outer periphery of the rotation link member, a function for preventing the bearings from removing from the V-shaped groove is provided. Since the V-shaped groove is in contact (point contact) with the curved surface portions without rubbing the curved surface portions, the effect of reducing generation of dusts can be obtained. Further, since the space, in which the movable member (link mechanism) such as the drive source, the rotation link member, and the like are disposed, is partitioned from the process space, in which the etching and the like are performed, by the partition, the particles, which are generated in the space in which the link mechanism is disposed and flow out into the process space, can be reduced.

### Description of the Reference Numerals

W substrate

P process space

1 ion beam etching apparatus (IBE apparatus)

3 vacuum vessel

5 ion beam source (IBS)

5a ion emitting portion (process-source-emitting-portion)

7 substrate stage

7a substrate holding portion

8 partition

9, 39 shutter device

11, 41 shutter plate

11a linear portion

13, 13a, 13b, 43 shutter rotating shaft

14 extending portion

15, 16, 17, 18 coupling portion

19 V-shaped groove (groove portion)

21 link mechanism

23 rotation link member

25, 45 couple link member

27 drive link member

29 drive source

29a drive rotating shaft

31 bearing

31a curved surface portion (convex portion)

1. A shutter device comprising a plurality of shutter plates which shield between a process-generation-source and a substrate disposed in a vacuum vessel comprising:
the shutter plates which are rotated about rotating shafts supported by the vacuum vessel;
a rotation-link-member rotatably disposed around the process-generation-source; and
a drive source which drives the rotation-link-member in rotation,
wherein the rotation-link-member is disposed surrounding a process-source-emitting-portion of the process-generation-source, and
as the rotation-link-member rotates, the shutter plates rotate about the rotating shafts.

2. The shutter device according to claim 1, wherein the shutter plates are geometrically disposed in symmetry.

3. The shutter device according to claim 1, wherein the shutter plates comprise coupling portions at positions away from the rotating shafts at a predetermined distance and further comprise couple link members which transmit power between the rotation-link-member and the coupling portions of the shutter plates.

4. The shutter device according claim 1,
wherein an outer periphery of the rotation-link-member is rotatably supported by at least three bearings,
a groove portion is formed around the outer periphery of the rotation-link-member in contact with the bearings,
convex portions having an arc-shaped cross section are formed around outer peripheries of the bearings in contact with the outer periphery of the rotation-link-member, and
the respective convex portions are in contact with the groove portion.

5. The shutter device according to claim 1,
wherein an outer periphery of the rotation-link-member is rotatably supported by at least three bearings,
a convex portion having an arc-shaped cross section is formed around the outer periphery of the rotation-link-member in contact with the bearings,
groove portions are formed around outer peripheries of the bearings in contact with the outer periphery of the rotation-link-member, and
the respective convex portions are in contact with the groove portions.

6. The shutter device according to claim 1, comprising a drive link member which transmits power between the drive source and the rotation-link-member.

7. The shutter device according to claim 1, comprising only one set of the drive source.

8. The shutter device according to claim 1, comprising the shutter plates having two plates.

9. The shutter device according to claim 1, comprising the shutter plates having eight plates.

10. A vacuum processing apparatus comprising the shutter device according to claim 1.
